(19) United States
(12) Patent Application Publication
(10) Pub. No.: US 2026/0238165 A1
(43) Pub. Date: Aug. 13, 2026

(54) POWER AMPLIFIER CIRCUIT AND COMMUNICATION CIRCUIT

(71) Applicant: Murata Manufacturing Co., Ltd., Nagaokakyo-shi (JP)

(72) Inventor: Kenji TAHARA, Nagaokakyo-shi (JP)

(21) Appl. No.: 19/459,171

(22) Filed: Jan. 26, 2026

(30) Foreign Application Priority Data
Feb. 10, 2025 (JP) 2025-020345

(51) Int. Cl. H03F 1/02; H03F 3/24; H04B 1/04

(52) U.S. Cl. CPC H03F 1/0288; H03F 3/245; H04B 1/0475; H03F 2200/171; H03F 2200/451; H04B 2001/045

(57) ABSTRACT

A power amplifier circuit comprising: a first amplifier, a second amplifier, a third amplifier, and a fourth amplifier; a first Marchand balun having a first terminal electrically connected to an output terminal of the first amplifier, a second terminal electrically connected to an output terminal of the second amplifier, and a third terminal electrically connected to an output terminal; a second Marchand balun having a first terminal electrically connected to an output terminal of the third amplifier, and a second terminal electrically connected to an output terminal of the fourth amplifier; and a filter electrically connected between a fourth terminal of the first Marchand balun and a third terminal of the second Marchand balun.

### CROSS REFERENCE TO RELATED APPLICATION

This application claims priority from Japanese Patent Application No. 2025-020345, filed on Feb. 10, 2025. The content of this application is incorporated herein by reference in its entirety.

### BACKGROUND OF THE DISCLOSURE

### 1. Field of the Disclosure

The present disclosure relates to power amplifier circuits and communication circuits.

### 2. Description of the Related Art

International Publication No. 2022/254875 (Patent Document 1) describes a radio-frequency circuit capable of suppressing harmonic waves without degrading the transfer characteristics of the fundamental wave, both during operation and non-operation of the peaking amplifiers.

### BRIEF SUMMARY OF THE DISCLOSURE

In mobile communications (wireless communications), the use of higher frequencies is being studied to achieve high-capacity and high-speed communications. For example, the use of the sub-terahertz band, which is higher than the millimeter-wave band (for example, 28-gigahertz (GHz) band) for the fifth-generation mobile communication system (5G), is being studied for the sixth-generation mobile communication system (6G). An example of the sub-terahertz band is the D-band (for example, from 120 GHz to 140 GHZ).

The radio-frequency circuit described in Patent Document 1 uses a transformer, that is, a magnetically coupled transformer balun (MCT balun: magnetic coupled transformer balun). However, when a magnetically coupled transformer balun is used in the sub-terahertz band, the magnetically coupled transformer balun becomes too small in size, and the magnetic coupling between the first coil and the second coil becomes too strong, resulting in too large parasitic capacitance between the first coil and the second coil and too high loss. The radio-frequency circuit described in Patent Document 1 is therefore undesirable for amplifying sub-terahertz band frequencies.

The present disclosure has been made in consideration of the problem described above, and a possible benefit thereof is to enable amplification of high-frequency signals.

A power amplifier circuit according to an aspect of the present disclosure includes: a first amplifier, a second amplifier, a third amplifier, and a fourth amplifier; a first Marchand balun having a first terminal electrically connected to an output terminal of the first amplifier, a second terminal electrically connected to an output terminal of the second amplifier, and a third terminal electrically connected to an output terminal; a second Marchand balun having a first terminal electrically connected to an output terminal of the third amplifier, and a second terminal electrically connected to an output terminal of the fourth amplifier; and a filter electrically connected between a fourth terminal of the first Marchand balun and a third terminal of the second Marchand balun. The filter includes a first portion and a second portion that are disposed on a substrate. The first portion includes a third portion having a length in a first direction when viewed perpendicularly to the substrate, the length resulting in a predetermined characteristic impedance, and a fourth portion extending in a second direction that intersects the first direction when viewed perpendicularly to the substrate, the fourth portion extending from a first edge of the third portion, the first edge being located on a side in the second direction, the fourth portion having a length in the second direction, the length being one-fourth of a wavelength of a radio-frequency signal. The second portion includes a fifth portion having a length in the first direction when viewed perpendicularly to the substrate, the length resulting in the characteristic impedance, and a sixth portion extending in a third direction opposite to the second direction when viewed perpendicularly to the substrate, the sixth portion extending from a second edge of the fifth portion, the second edge being located on a side in the third direction, the sixth portion having a length in the third direction, the length being one-fourth of a wavelength of a radio-frequency signal. The fourth portion and the sixth portion are spaced apart from and parallel to each other when viewed perpendicularly to the substrate, and are configured to provide line coupling.

A communication circuit according to an aspect of the present disclosure includes: a radio-frequency signal processing circuit configured to process a radio-frequency signal; and the power amplifier circuit described above, the power amplifier circuit being provided in a signal path between the radio-frequency signal processing circuit and an antenna.

The present disclosure enables amplification of high-frequency signals.

### BRIEF DESCRIPTION OF THE SEVERAL VIEWS OF THE DRAWINGS

FIG. 1 illustrates the configuration of a differential amplifier circuit according to a first comparative example;

FIG. 2 illustrates the circuit simulation results for the differential amplifier circuit according to the first comparative example;

FIG. 3 illustrates the circuit simulation results for the differential amplifier circuit according to the first comparative example;

FIG. 4 illustrates the circuit simulation results for the differential amplifier circuit according to the first comparative example;

FIG. 5 illustrates the circuit simulation results for the differential amplifier circuit according to the first comparative example;

FIG. 6 illustrates the return loss, the variation in the load impedance of an antenna, and the power variation in the power amplifier circuit when the antenna reflection coefficient is varied;

FIG. 7 illustrates the configuration of a Doherty amplifier circuit according to a second comparative example;

FIG. 8 illustrates the circuit simulation results for the Doherty amplifier circuit according to the second comparative example;

FIG. 9 illustrates the configuration of the Doherty amplifier circuit according to the second comparative example;

FIG. 10 illustrates the circuit simulation results for the Doherty amplifier circuit according to the second comparative example;

FIG. 11 illustrates the configuration of a Doherty amplifier circuit according to a third comparative example;

FIG. 12 illustrates the circuit simulation results for the Doherty amplifier circuit according to the third comparative example;

FIG. 13 illustrates the circuit simulation results for the Doherty amplifier circuit according to the third comparative example;

FIG. 14 illustrates the circuit simulation results for the Doherty amplifier circuit according to the third comparative example;

FIG. 15 illustrates the circuit simulation results for the Doherty amplifier circuit according to the third comparative example;

FIGS. 16A, 16B, and 16C focus on the first-branch amplifier of the peaking amplifiers of the Doherty amplifier circuit according to the third comparative example;

FIG. 17 illustrates the S-parameters at the output-terminal side of the first-branch amplifier of the peaking amplifiers of the Doherty amplifier circuit according to the third comparative example;

FIG. 18 illustrates the configuration of a differential amplifier circuit according to a first embodiment;

FIG. 19 illustrates the structure of a filter in a power amplifier circuit according to the first embodiment;

FIG. 20 illustrates the equivalent circuit of the filter in the power amplifier circuit according to the first embodiment;

FIG. 21 illustrates the circuit simulation results for the filter in the differential amplifier circuit according to the first embodiment;

FIG. 22 illustrates the circuit simulation results for the filter in the differential amplifier circuit according to the first embodiment;

FIG. 23 illustrates the circuit simulation results for the filter in the differential amplifier circuit according to the first embodiment;

FIG. 24 illustrates the circuit simulation results for the filter in the differential amplifier circuit according to the first embodiment;

FIG. 25 illustrates the configuration of the differential amplifier circuit in the final stage of the power amplifier circuit according to the first embodiment;

FIG. 26 illustrates the circuit simulation results for the differential amplifier circuit in the final stage of the power amplifier circuit according to the first embodiment;

FIG. 27 illustrates the circuit simulation results for the differential amplifier circuit in the final stage of the power amplifier circuit according to the first embodiment;

FIG. 28 illustrates the circuit simulation results for the differential amplifier circuit in the final stage of the power amplifier circuit according to the first embodiment;

FIG. 29 illustrates the circuit simulation results for the differential amplifier circuit in the final stage of the power amplifier circuit according to the first embodiment; and

FIG. 30 illustrates the configuration of a communication circuit according to a second embodiment.

### DETAILED DESCRIPTION OF THE DISCLOSURE

Hereinafter, preferred embodiments of the present disclosure will be described in detail with reference to the drawings. The present disclosure is not limited by these embodiments. The embodiments will be presented as illustrative examples. As one would anticipate, the configurational features described in the various embodiments may be partially replaced or combined. In the second and subsequent embodiments, descriptions of the features common to the first embodiment will not be repeated, and only different features will be described. In particular, the same effects and advantages achieved by the same configurational features will not be described in every embodiment.

### Example of Frequency Band

In the descriptions of the embodiments, the sub-terahertz band, which is being studied to be adopted in the sixth-generation mobile communication system (6G), is described as the target frequency band. However, this should not be interpreted as limiting the present disclosure. The sub-terahertz band is exemplified by the D-band. However, this should not be interpreted as limiting the present disclosure. The D-band ranges, for example, from 120 GHz to 140 GHz. However, this should not be interpreted as limiting the present disclosure. The center frequency is defined as 130 GHz. However, this should not be interpreted as limiting the present disclosure.

### Concepts of Embodiments

### (1) High Output Power

Radio waves in the sub-terahertz band are easily attenuated. Power amplifier circuits are thus required to provide high output power. One approach to achieving high output power in power amplifier circuits is to increase the size (for example, gate width) of a transistor (amplifying element). However, transistors have a phenomenon referred to as the “size effect.”

The size effect is a phenomenon in which increasing the transistor gate width or emitter size increases output power. However, because parasitic capacitance and parasitic inductance also increase, amplification operation at high frequencies is consequently limited.

The improvement in the performance of transistors with increasing size is limited due to the size effect. As a result, output power or efficiency does not increase in proportion to size.

For this reason, approaches other than increasing the size of transistors are needed to achieve high output power or high efficiency in power amplifier circuits.

Therefore, in the embodiments, a differential amplifier circuit is used as the power amplifier circuit. Differential amplifier circuits are capable of achieving high output power and exhibit preferable noise immunity.

### (2) Balun

A balun is required in the stage after the differential amplifier circuit. As described above, magnetically coupled transformer baluns (MCT baluns) are not suitable for the sub-terahertz band due to high loss. Thus, baluns other than magnetically coupled transformer baluns need to be used.

An example of baluns other than magnetically coupled transformer baluns is a Marchand balun. A Marchand balun includes quarter-wavelength coupling lines (λ/4 coupling lines). Marchand baluns have wide fractional band widths and exhibit low loss.

In lower frequency bands used in known technologies, Marchand baluns increase in size because the wavelengths are relatively long, and thus the quarter-wavelength coupling lines become relatively long. By contrast, Marchand baluns can decrease in size in the sub-terahertz band because the wavelengths are relatively short, and thus the quarter-wavelength coupling lines become relatively short.

Accordingly, Marchand baluns are used as the baluns in the embodiments.

### (3) High Efficiency

Envelope tracking technology is known as a technique for achieving high efficiency in power amplifier circuits. Envelope tracking technology varies the power supply voltage of transistors in amplifiers based on the envelope of the radio-frequency signal. Digital envelope tracking technology is also known, which discretely varies the power supply voltage of transistors in amplifiers based on the envelope of the radio-frequency signal.

In the use of digital envelope tracking technology, class-C amplifiers have higher back-off efficiencies than class-AB amplifiers.

Accordingly, Doherty amplifier circuits including carrier amplifiers implemented by class-AB amplifiers (or class-A amplifiers), and peaking amplifiers implemented by class-C amplifiers, are used as power amplifier circuits in the embodiments.

### Description of Circuit Examples

Based on the concepts described above, the circuits of first to third comparative examples and a first embodiment will be described.

As a first comparative example, a differential amplifier circuit using a Marchand balun will be described. As a second comparative example, a Doherty amplifier circuit that includes the differential amplifier circuit of the first comparative example will be described. As a third comparative example, a Doherty amplifier circuit that is an improvement of the Doherty amplifier circuit in the second comparative example will be described.

As a first embodiment, a power amplifier circuit (Doherty amplifier circuit) that is an improvement of the Doherty amplifier circuit in the third comparative example will be described.

In the first to third comparative examples and the first embodiment, the same constituent elements are assigned the same reference numerals, and descriptions thereof are omitted.

### First Comparative Example

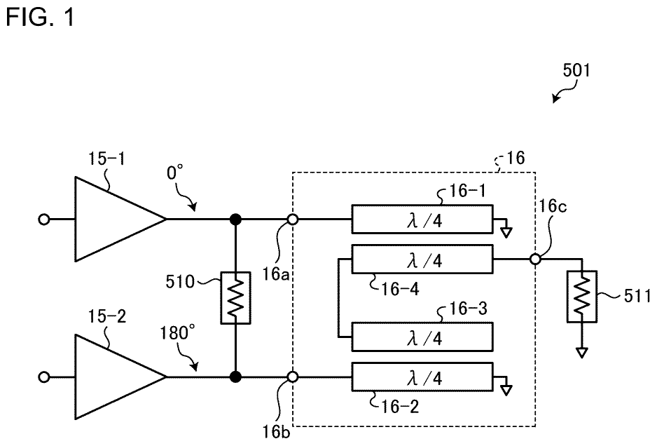

FIG. 1 illustrates the configuration of the differential amplifier circuit according to the first comparative example.

A differential amplifier circuit 501 includes amplifiers 15-1 and 15-2 and a Marchand balun 16. The Marchand balun 16 includes quarter-wavelength coupling lines 16-1 to 16-4.

The relative phase difference between the output signal of the amplifier 15-1 and the output signal of the amplifier 15-2 is 180°. For example, assuming that the phase of the output signal of the amplifier 15-1 is 0°, the phase of the output signal of the amplifier 15-2 is 180°.

The output terminal of the amplifier 15-1 is electrically connected to a terminal 16a of the Marchand balun 16. The output terminal of the amplifier 15-2 is electrically connected to a terminal 16b of the Marchand balun 16.

One end of the quarter-wavelength coupling line 16-1 is electrically connected to the terminal 16a. The other end of the quarter-wavelength coupling line 16-1 is electrically connected to a reference potential. A reference potential is exemplified by a ground potential. However, this should not be interpreted as limiting the present disclosure.

One end of the quarter-wavelength coupling line 16-2 is electrically connected to the terminal 16b. The other end of the quarter-wavelength coupling line 16-2 is electrically connected to a reference potential.

The quarter-wavelength coupling line 16-3 provides line coupling with the quarter-wavelength coupling line 16-2. One end of the quarter-wavelength coupling line 16-3 is open-circuited. The other end of the quarter-wavelength coupling line 16-3 is electrically connected to one end of the quarter-wavelength coupling line 16-4.

The quarter-wavelength coupling line 16-4 provides line coupling with the quarter-wavelength coupling line 16-1. The other end of the quarter-wavelength coupling line 16-4 is electrically connected to a terminal 16c.

The terminal 16c of the Marchand balun 16 is electrically connected to one end of a load 511.

In FIG. 1, impedance 510 at the output ends of the transistors (not illustrated) in the amplifiers 15-1 and 15-2 is illustrated in FIG. 1. The impedance 510 does not represent any element. The impedance 510 correlates with a reflection coefficient Γ of the Marchand balun 16 and with the S-parameter S(1, 1).

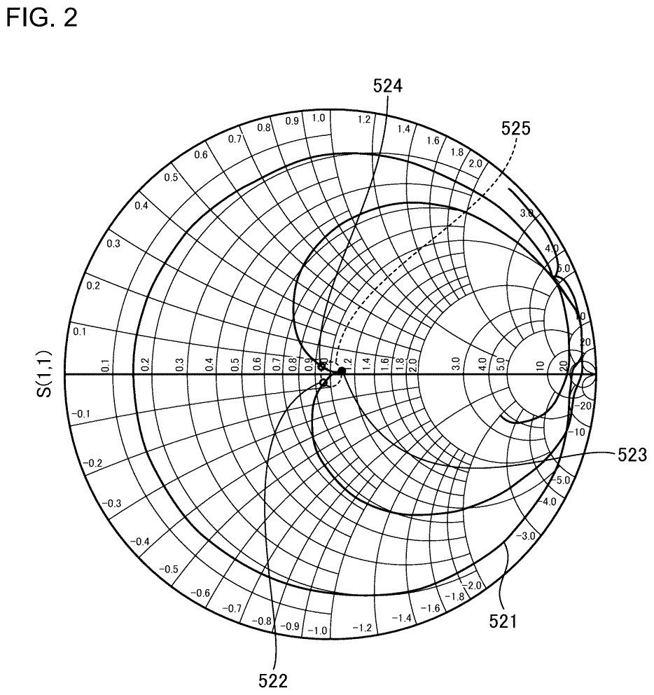

FIGS. 2 to 5 illustrate the circuit simulation results for the differential amplifier circuit according to the first comparative example.

FIG. 2 illustrates the circuit simulation results for the S-parameter S(1, 1) of the Marchand balun 16 in the differential amplifier circuit 501.

The line 521 illustrates S(1, 1) when the frequency of the radio-frequency signal is varied from 40 GHz to 300 GHZ. The point 522 indicates S(1,1) at a frequency of 120 GHZ. The point 523 indicates S(1, 1) at a frequency of 130 GHZ. The point 524 indicates S(1,1) at a frequency of 140 GHz.

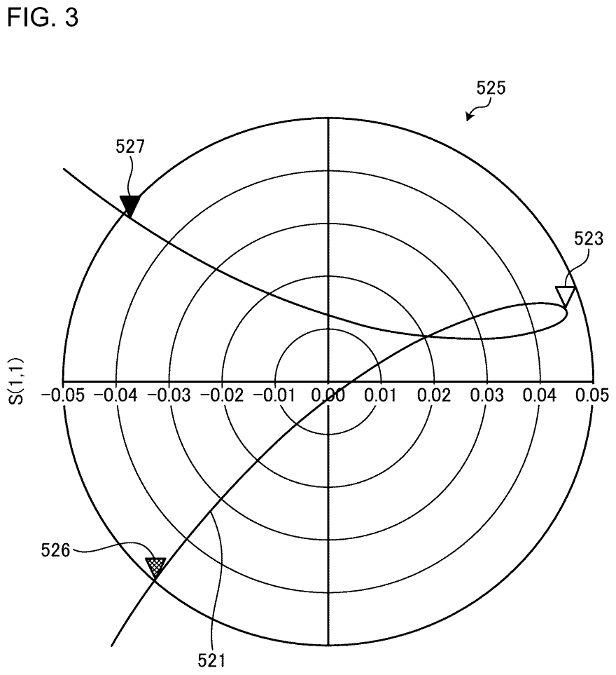

FIG. 3 is an enlarged view of the region 525 in FIG. 2. In the region 525, the output impedance of the transistors in the amplifiers 15-1 and 15-2 is at the center, and the radius is 0.05 (the absolute value of the reflection coefficient Γ is less than or equal to 0.05, that is, |Γ|≤0.05).

In the present disclosure, the range in which |Γ|≤ 0.05 is defined as the frequency band. The reasons for this will be described later.

The point 526 indicates the minimum frequency at which the S-parameter S(1, 1) is less than or equal to 0.05. The frequency at the point 526 is 119.7 GHZ. The point 527 indicates the maximum frequency at which the S-parameter S(1, 1) is less than or equal to 0.05. The frequency at the point 527 is 140.1 GHZ.

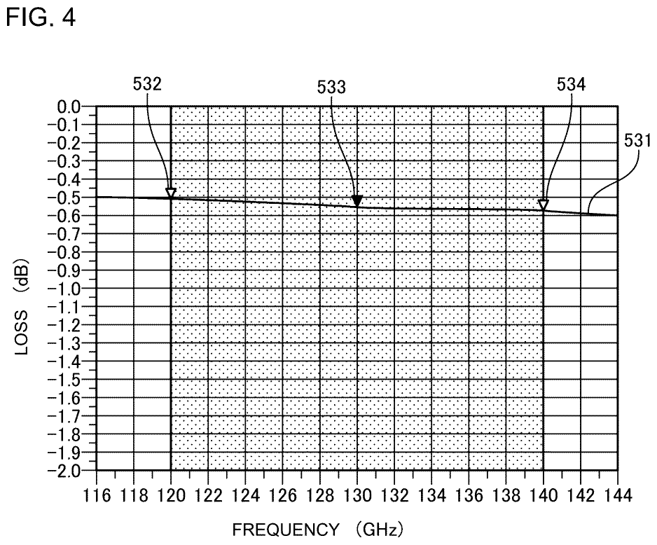

FIG. 4 illustrates the circuit simulation results for loss in the differential amplifier circuit 501.

The line 531 illustrates the loss (dB) when the frequency of the radio-frequency signal is varied from 116 GHz to 144 GHz. The point 532 indicates the loss (dB) at a frequency of 120 GHZ. The loss at the point 532 is −0.502 dB. The point 533 indicates the loss (dB) at a frequency of 130 GHz. The loss at the point 533 is −0.547 dB. The point 534 indicates the loss (dB) at a frequency of 140 GHZ. The loss at the point 534 is −0.567 dB.

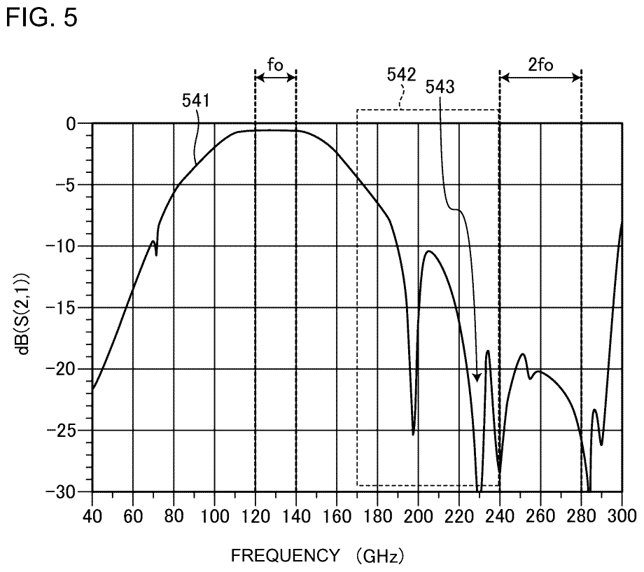

FIG. 5 illustrates the circuit simulation results for the S-parameter S(2,1) (forward transmission characteristics) of the differential amplifier circuit 501.

The line 541 illustrates S(2,1) when the frequency of the radio-frequency signal is varied from 40 GHz to 300 GHz. The frequency band fo ranges from 120 GHz to 140 GHz. The frequency band 2fo ranges from 240 GHz to 280 GHz.

The frequency band fo is preferable because the frequency band fo has no resonance point and S(2,1) is nearly constant.

As illustrated in FIGS. 2 to 5, the differential amplifier circuit 501 has preferable characteristics.

Referring to FIG. 5, the frequency band 542, which ranges from 170 GHz to 240 GHz, includes multiple resonance points. For example, the resonance point 543 is located near a frequency of 230 GHZ.

### Reason for Selecting |Γ|≤0.05 Frequency Band

The reason for selecting the |Γ|≤0.05 frequency band will be described.

A typical antenna is assumed as the load for the differential amplifier circuit 501. The output power Pout of the differential amplifier circuit 501 at saturation is expressed by the following equation (1), using the impedance R_{L} of the antenna load, the power supply voltage V_{cc}, and the saturation voltage Vₛₐₜ.

$$Pout ( dBm ) = 10 \times log \{ {( ( 2 {V}_{cc} - {V}_{sat} ) )}^{2} / 8 {R}_{L} \times {10}^{- 3} \} \qquad ( 1 )$$

The reflection coefficient Γ of the antenna is expressed by the following equation (2), using the characteristic impedance Z₀ (=50Ω) and the load impedance Z_{L} of the antenna.

$$Γ = \vert \frac{{Z}_{L} - {Z}_{0}}{{Z}_{L} + {Z}_{0}} \vert \qquad ( 2 )$$

The return loss is expressed by the following equation (3), using the reflection coefficient Γ of the antenna.

$$Return loss = - 20 \times log \vert Γ \vert \qquad ( 3 )$$

By using the equations (1) to (3), the return loss, the variation in the load impedance of the antenna, and the power variation in the differential amplifier circuit 501 when the antenna reflection coefficient Γ is varied can be calculated.

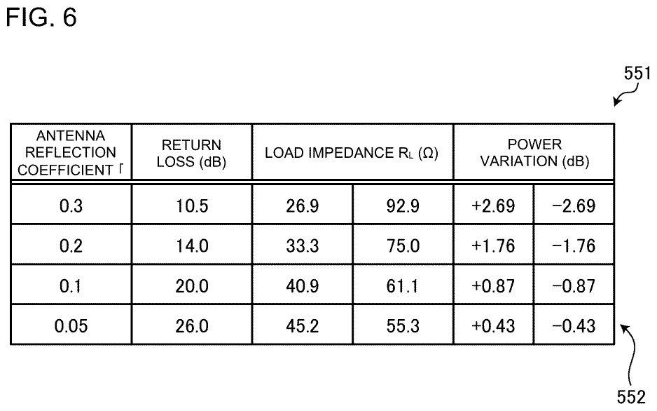

FIG. 6 illustrates the return loss, the variation in the load impedance of the antenna, and the power variation in the differential amplifier circuit 501 when the antenna reflection coefficient Γ is varied.

The power variation in the differential amplifier circuit 501 is required to be within 1 dB. To maintain the power variation in the differential amplifier circuit 501 within 1 dB, |Γ|≤0.05 as presented in the fourth row 552 of the table 551 (see FIG. 6). The return loss under this condition is greater than or equal to 26 dB.

### Second Comparative Example

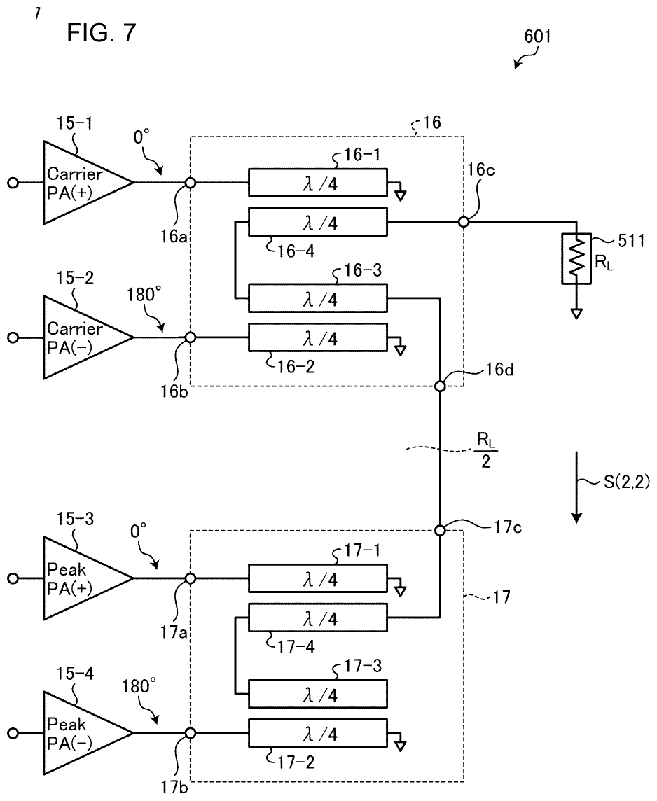

FIG. 7 illustrates the configuration of the Doherty amplifier circuit according to the second comparative example.

A Doherty amplifier circuit 601 includes amplifiers 15-1 to 15-4, and Marchand baluns 16 and 17. The Marchand balun 17 includes quarter-wavelength coupling lines 17-1 to 17-4.

The relative phase difference between the output signal of the amplifier 15-1 and the output signal of the amplifier 15-3 is 0°. For example, assuming that the phase of the output signal of the amplifier 15-1 is 0°, the phase of the output signal of the amplifier 15-2 is 180°, the phase of the output signal of the amplifier 15-3 is 0°, the phase of the output signal of the amplifier 15-4 is 180°.

The amplifiers 15-1 and 15-2 correspond to carrier amplifiers that operate as a differential pair. The amplifiers 15-3 and 15-4 correspond to peaking amplifiers that operate as a differential pair.

The output terminal of the amplifier 15-3 is electrically connected to a terminal 17a of the Marchand balun 17. The output terminal of the amplifier 15-4 is electrically connected to a terminal 17b of the Marchand balun 17.

One end of the quarter-wavelength coupling line 17-1 is electrically connected to the terminal 17a. The other end of the quarter-wavelength coupling line 17-1 is electrically connected to a reference potential.

One end of the quarter-wavelength coupling line 17-2 is electrically connected to the terminal 17b. The other end of the quarter-wavelength coupling line 17-2 is electrically connected to a reference potential.

The quarter-wavelength coupling line 17-3 provides line coupling with the quarter-wavelength coupling line 17-2. One end of the quarter-wavelength coupling line 17-3 is open-circuited. The other end of the quarter-wavelength coupling line 17-3 is electrically connected to one end of the quarter-wavelength coupling line 17-4.

The quarter-wavelength coupling line 17-4 provides line coupling with the quarter-wavelength coupling line 17-1. The other end of the quarter-wavelength coupling line 17-4 is electrically connected to a terminal 17c.

The terminal 17c of the Marchand balun 17 is electrically connected to a terminal 16d of the Marchand balun 16. The terminal 16d of the Marchand balun 16 is electrically connected to one end of the quarter-wavelength coupling line 16-3.

Accordingly, the output line of the Marchand balun 17 (the quarter-wavelength coupling lines 17-3 and 17-4) and the output line of the Marchand balun 16 (the quarter-wavelength coupling lines 16-3 and 16-4) are connected in series.

As a result, the voltage of the output signal of the carrier amplifiers (the amplifiers 15-1 and 15-2) and the voltage of the output signal of the peaking amplifiers (the amplifiers 15-3 and 15-4) are combined (added).

When both the carrier amplifiers (the amplifiers 15-1 and 15-2) and the peaking amplifiers (the amplifiers 15-3 and 15-4) operate, one-half of the impedance R_{L} of the load 511 (=R_{L}/2) appears between the terminal 16d of the Marchand balun 16 and the terminal 17c of the Marchand balun 17.

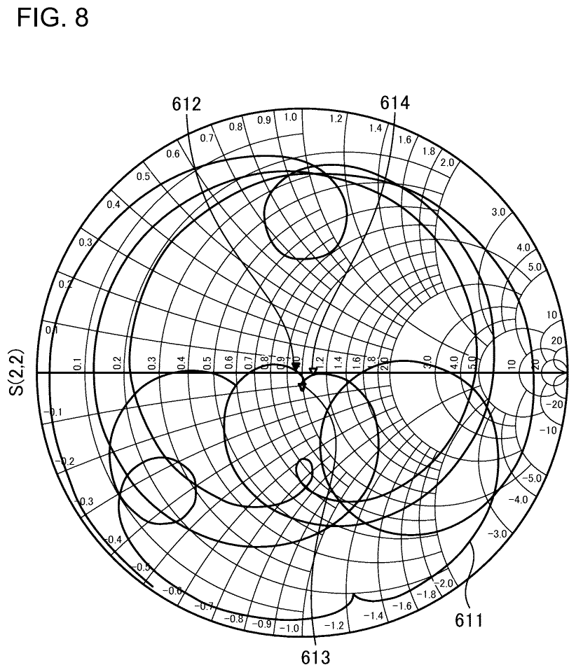

FIG. 8 illustrates the circuit simulation results for the Doherty amplifier circuit according to the second comparative example.

FIG. 8 illustrates the circuit simulation results for the S-parameter S(2,2) of the Marchand balun 17 when both the carrier amplifiers (the amplifiers 15-1 and 15-2) and the peaking amplifiers (the amplifiers 15-3 and 15-4) operate.

The line 611 illustrates the S-parameter S(2,2) of the Marchand balun 17 when the frequency of the radio-frequency signal is varied from 40 GHz to 300 GHz. The point 612 indicates S(2,2) at a frequency of 120 GHz. The point 613 indicates S(2,2) at a frequency of 130 GHz. The point 614 indicates S(2,2) at a frequency of 140 GHz.

As illustrated in FIG. 8, when both the carrier amplifiers (the amplifiers 15-1 and 15-2) and the peaking amplifiers (the amplifiers 15-3 and 15-4) operate, S(2,2) fluctuates to a small extent, which is preferable.

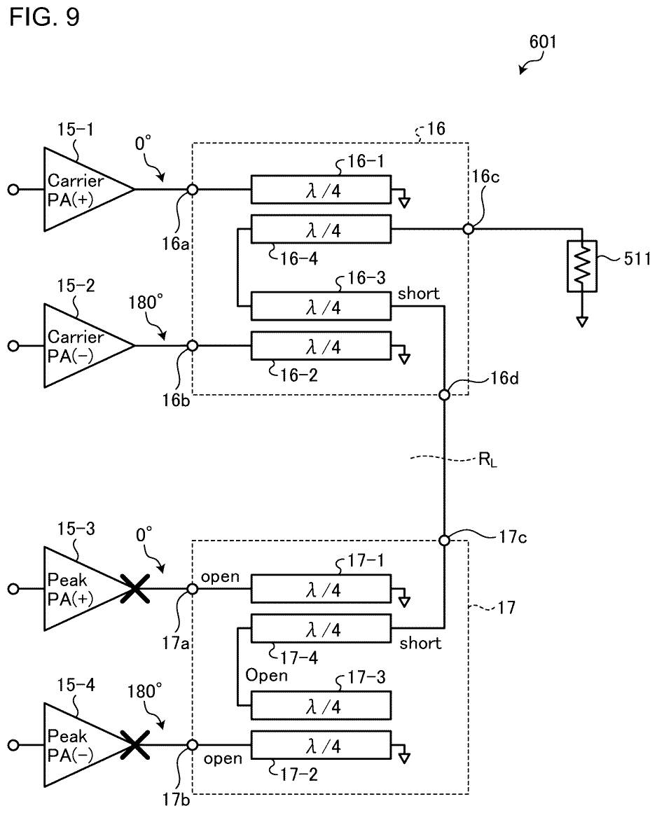

FIG. 9 illustrates the configuration of the Doherty amplifier circuit according to the second comparative example.

FIG. 9 illustrates the case where the carrier amplifiers (the amplifiers 15-1 and 15-2) operate while the peaking amplifiers (the amplifiers 15-3 and 15-4) do not operate.

In this case, one end of the quarter-wavelength coupling line 17-1 is open-circuited. One end of the quarter-wavelength coupling line 17-2 is open-circuited. An open circuit is formed between the other end of the quarter-wavelength coupling line 17-3 and one end of the quarter-wavelength coupling line 17-4. A short circuit is formed between the other end of the quarter-wavelength coupling line 17-4 and one end of the quarter-wavelength coupling line 16-3.

The same impedance as the impedance R_{L} of the load 511 appears between the terminal 16d of the Marchand balun 16 and the terminal 17c of the Marchand balun 17.

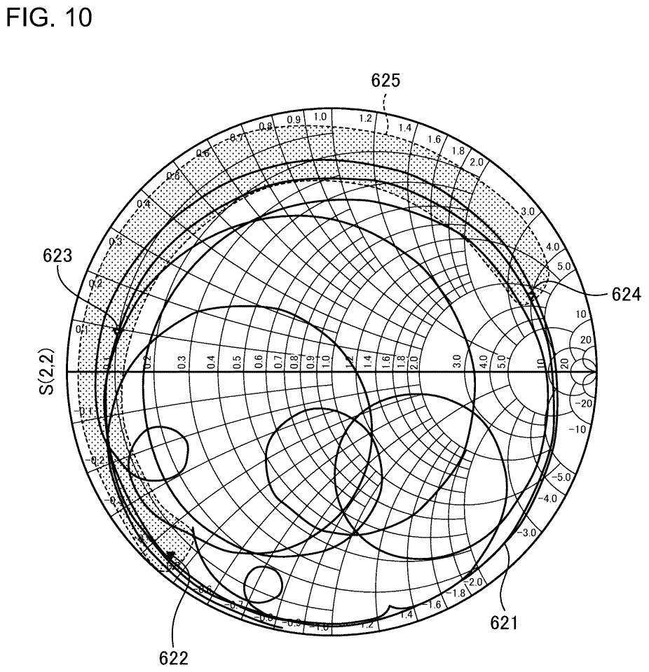

FIG. 10 illustrates the circuit simulation results for the Doherty amplifier circuit according to the second comparative example.

FIG. 10 illustrates the circuit simulation results for the S-parameter S(2,2) of the Marchand balun 17 when the carrier amplifiers (the amplifiers 15-1 and 15-2) operate while the peaking amplifiers (the amplifiers 15-3 and 15-4) do not operate.

The line 621 illustrates the S-parameter S(2,2) of the Marchand balun 17 when the frequency of the radio-frequency signal is varied from 40 GHz to 300 GHz. The point 622 indicates S(2,2) at a frequency of 120 GHZ. The point 623 indicates S(2,2) at a frequency of 130 GHZ. The point 624 indicates S(2,2) at a frequency of 140 GHz.

As illustrated in FIG. 10, when the carrier amplifiers (the amplifiers 15-1 and 15-2) operate while the peaking amplifiers (the amplifiers 15-3 and 15-4) do not operate, S(2,2) fluctuates over the wide range 625. Thus, the Doherty amplifier circuit according to the second comparative example has undesirable characteristics.

### Third Comparative Example

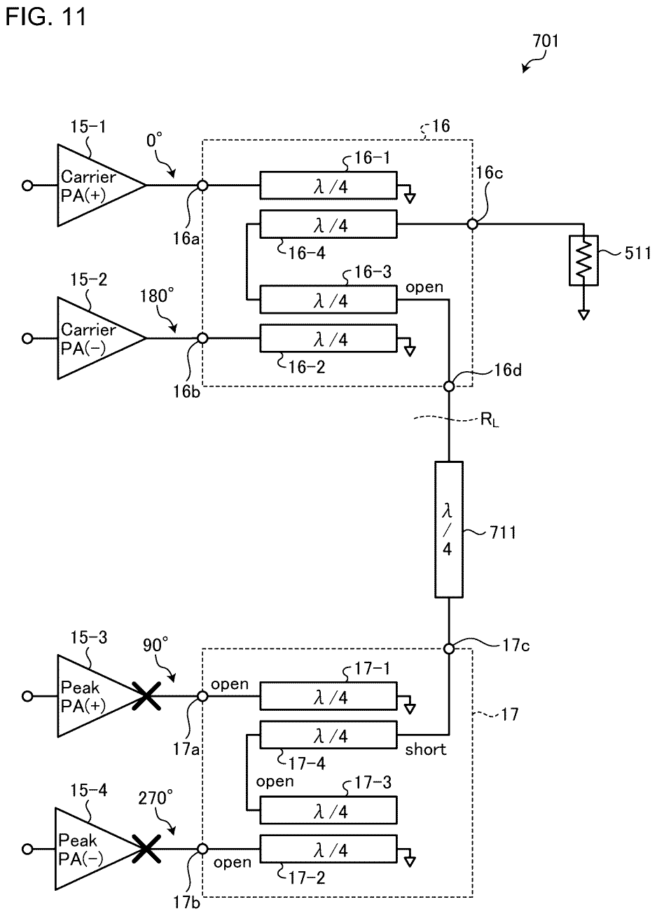

FIG. 11 illustrates the configuration of the Doherty amplifier circuit according to the third comparative example.

A Doherty amplifier circuit 701 further includes a quarter-wavelength coupling line 711 in addition to the Doherty amplifier circuit 601 (see FIGS. 7 and 9).

One end of the quarter-wavelength coupling line 711 is electrically connected to the terminal 17c of the Marchand balun 17. The other end of the quarter-wavelength coupling line 711 is electrically connected to the terminal 16d of the Marchand balun 16.

The quarter-wavelength coupling line 711 introduces a delay of 90°. As a result, the relative phase difference between the output signal of the amplifier 15-1 and the output signal of the amplifier 15-3 is 90°. For example, assuming that the phase of the output signal of the amplifier 15-1 is 0°, the phase of the output signal of the amplifier 15-2 is 180°, the phase of the output signal of the amplifier 15-3 is 90°, and the phase of the output signal of the amplifier 15-4 is 270°.

With this configuration, after the output signals of the peaking amplifiers (the amplifiers 15-3 and 15-4) pass through the quarter-wavelength coupling line 711, the phase of the output signals of the peaking amplifiers (the amplifiers 15-3 and 15-4) becomes aligned with the phase of the output signals of the carrier amplifiers (the amplifiers 15-1 and 15-2).

The same impedance as the impedance RI of the load 511 appears between the terminal 16d of the Marchand balun 16 and the other end of the quarter-wavelength coupling line 711.

Because the quarter-wavelength coupling line 711 is provided, one end of the quarter-wavelength coupling line 16-3 is open-circuited when the peaking amplifiers (the amplifiers 15-3 and 15-4) do not operate.

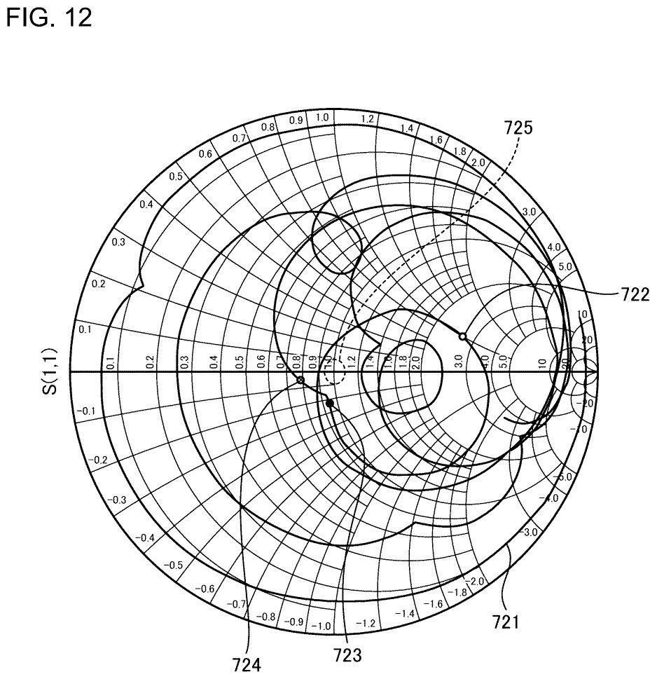

FIGS. 12 to 15 illustrate the circuit simulation results for the Doherty amplifier circuit according to the third comparative example.

FIG. 12 illustrates the circuit simulation results for the S-parameter S(1, 1) of the Marchand balun 16 when the carrier amplifiers (the amplifiers 15-1 and 15-2) operate while the peaking amplifiers (the amplifiers 15-3 and 15-4) do not operate.

The line 721 illustrates S(1, 1) when the frequency of the radio-frequency signal is varied from 40 GHz to 300 GHz. The point 722 indicates S(1,1) at a frequency of 120 GHZ. The point 723 indicates S(1, 1) at a frequency of 130 GHZ. The point 724 indicates S(1, 1) at a frequency of 140 GHz.

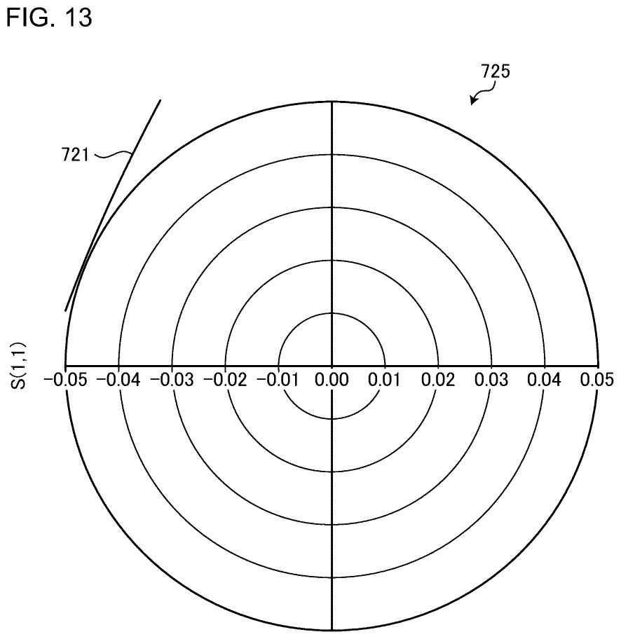

FIG. 13 is an enlarged view of the region 725 in FIG. 12. In the region 725, the output impedance of the transistors in the amplifiers 15-1 and 15-2 is at the center, and the radius is 0.05 (the absolute value of the reflection coefficient Γ is less than or equal to 0.05, that is, |Γ|≤0.05).

The line 721 does not pass through the region 725. This means that |Γ|≤0.05 is not satisfied at any frequency.

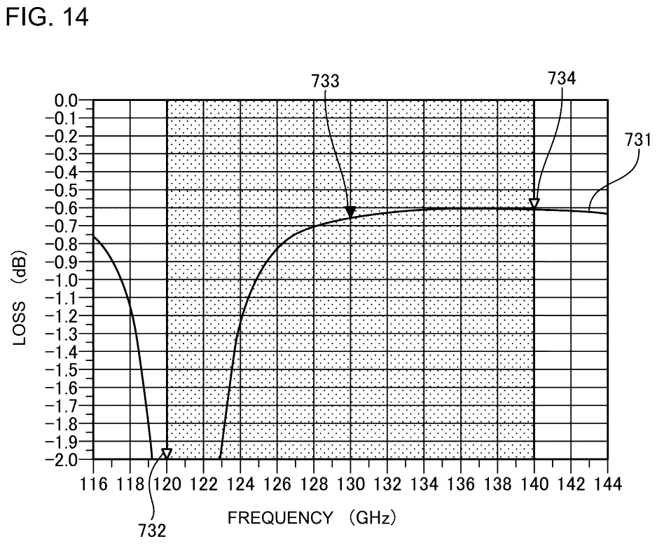

FIG. 14 illustrates the circuit simulation results for loss when the carrier amplifiers (the amplifiers 15-1 and 15-2) operate while the peaking amplifiers (the amplifiers 15-3 and 15-4) do not operate.

The line 731 illustrates the loss (dB) when the frequency of the radio-frequency signal is varied from 116 GHz to 144 GHZ. The point 732 indicates the loss (dB) at a frequency of 120 GHz. The loss at the point 732 is −3.699 dB. The point 733 indicates the loss (dB) at a frequency of 130 GHz. The loss at the point 733 is −0.656 dB. The point 734 indicates the loss (dB) at a frequency of 140 GHz. The loss at the point 734 is −0.614 dB.

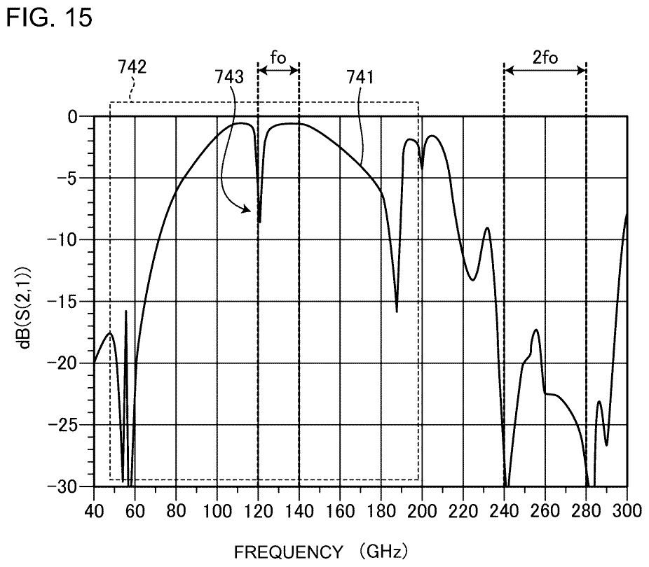

FIG. 15 illustrates the circuit simulation results for the S-parameter S(2,1) (forward transmission characteristics) of the Doherty amplifier circuit 701.

The line 741 illustrates S(2,1) when the frequency of the radio-frequency signal is varied from 40 GHz to 300 GHz. The frequency band fo ranges from 120 GHz to 140 GHZ. The frequency band 2fo ranges from 240 GHz to 280 GHz.

In the differential amplifier circuit 501 according to the first comparative example, the frequency band 542 (see FIG. 5), which ranges from 170 GHz to 240 GHZ, includes multiple resonance points. For example, the resonance point 543 is located near a frequency of 230 GHz.

By contrast, in the Doherty amplifier circuit 701 according to the third comparative example, multiple resonance points are shifted, with respect to frequency, to the frequency band 742, which ranges from 50 GHz to 190 GHZ, due to the presence of the quarter-wavelength coupling line 711. For example, the resonance point 543, which is located near a frequency of 230 GHz in the differential amplifier circuit 501 according to the first comparative example, is shifted, with respect to frequency, to the resonance point 743 near a frequency of 120 GHz in the Doherty amplifier circuit 701 according to the third comparative example.

As described above, the Doherty amplifier circuit 701 has undesirable characteristics. The causes for this will be discussed below.

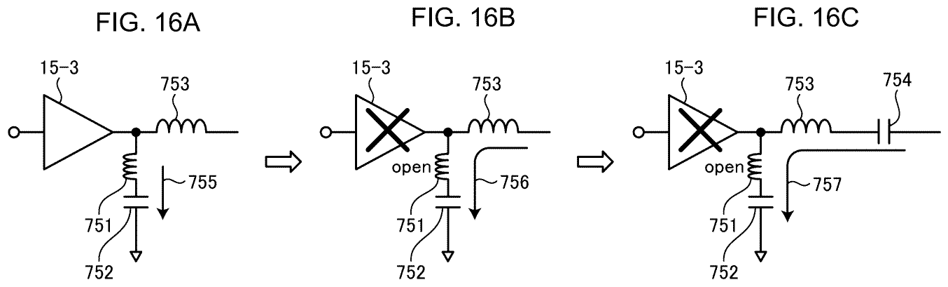

FIGS. 16A, 16B, and 16C focus on the first-branch amplifier of the peaking amplifiers of the Doherty amplifier circuit according to the third comparative example.

FIG. 16A illustrates the case where the first-branch amplifier 15-3 of the peaking amplifiers of the Doherty amplifier circuit 701 operates. FIGS. 16B and 16C illustrate the case where the amplifier 15-3 does not operate.

A parasitic inductance 751 and a parasitic capacitance 752 connected in series are present between the output terminal of the amplifier 15-3 and a reference potential. One end of an inductance 753 is connected to the output terminal of the amplifier 15-3. The inductance 753 is the inductance of the path extending from the amplifier 15-3 to the terminal 16c of the Marchand balun 16.

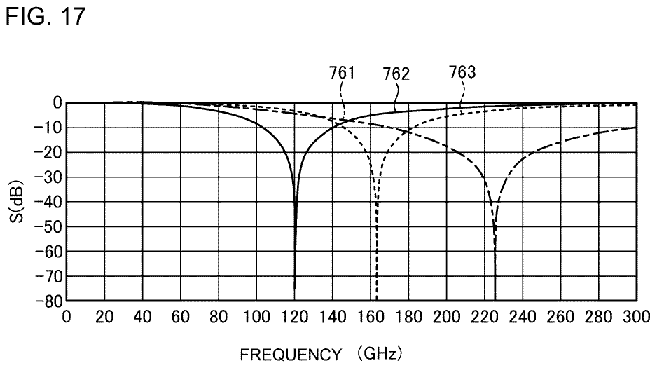

FIG. 17 illustrates the S-parameters at the output-terminal side of the first-branch amplifier of the peaking amplifiers of the Doherty amplifier circuit according to the third comparative example.

The line 761 in FIG. 17 illustrates the S-parameters in FIG. 16A. The line 762 illustrates the S-parameters in FIG. 16B. The line 763 illustrates the S-parameters in FIG. 16C.

As illustrated in FIG. 16A, when the amplifier 15-3 operates, an LC series resonant circuit 755 (the parasitic inductance 751 and the parasitic capacitance 752) resonates (see the line 761 in FIG. 17). The frequency at the resonance point is approximately 225 GHZ.

As illustrated in FIG. 16B, when the amplifier 15-3 does not operate, an LC series resonant circuit 756 (the parasitic inductance 751, the parasitic capacitance 752, and the inductance 753) resonates (see the line 762 in FIG. 17). The resonant frequency of the LC series resonant circuit 756 is shifted to a lower frequency due to the addition of the inductance 753, compared to the resonant frequency of the LC series resonant circuit 755. The frequency at the resonance point is approximately 120 GHZ.

To shift the resonant frequency of the LC series resonant circuit 756 to a higher frequency, one approach is to connect a capacitor 754 having a sufficiently small capacitance in series with the inductance 753, as illustrated in FIG. 16C.

As illustrated in FIG. 16C, when the amplifier 15-3 does not operate, an LC series resonant circuit 757 (the parasitic inductance 751, the parasitic capacitance 752, the inductance 753, and the capacitor 754) resonates (see the line 763 in FIG. 17). The resonant frequency of the LC series resonant circuit 757 is shifted to a higher frequency due to the addition of the capacitor 754, compared to the resonant frequency of the LC series resonant circuit 756. The frequency at the resonance point is approximately 165 GHZ.

As described above, by connecting the capacitor 754 in series with the inductance 753, the frequency at the resonance point is moved outside the frequency band fo.

However, the addition of the capacitor 754 prevents the desirable wide-band matching from being achieved, resulting in narrow-band matching.

### First Embodiment

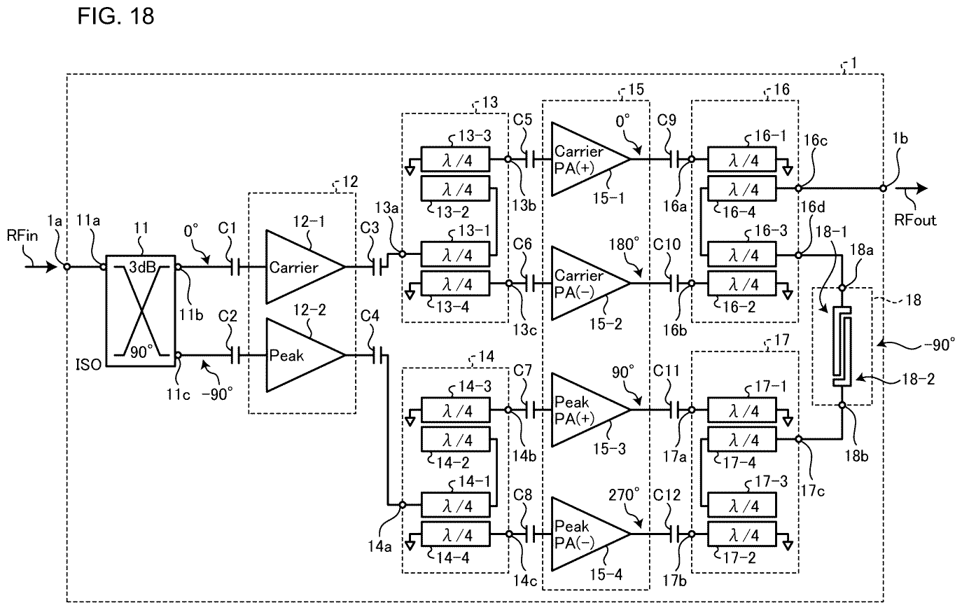

FIG. 18 illustrates the configuration of the differential amplifier circuit according to the first embodiment.

A power amplifier circuit 1 amplifies a radio-frequency signal RFin, which is inputted to a terminal 1a, and outputs an amplified radio-frequency signal RFout from a terminal 1b.

The terminal 1a is, for example, electrically connected to a radio-frequency signal processing circuit (RFIC). However, this should not be interpreted as limiting the present disclosure. The terminal 1b is, for example, electrically connected to an element such as an antenna or a front-end circuit. However, this should not be interpreted as limiting the present disclosure.

The power amplifier circuit 1 includes a splitter 11, a driver-stage (first-stage) amplifier circuit 12, Marchand baluns 13 and 14, a final-stage (power-stage) amplifier circuit 15, Marchand baluns 16 and 17, and a filter 18.

The splitter 11 is a 90° hybrid circuit. However, this should not be interpreted as limiting the present disclosure. A terminal 11a of the splitter 11 is electrically connected to the terminal 1a. The splitter 11 outputs, based on a single-ended (unbalanced) radio-frequency signal RFin input to the terminal 11a, a radio-frequency signal of a first phase from a terminal 11b and a radio-frequency signal of a second phase from a terminal 11c.

The relative phase between the radio-frequency signal outputted from the terminal 11b and the radio-frequency signal outputted from the terminal 11c is −90°. For example, assuming that the phase of the radio-frequency signal outputted from the terminal 11b is 0°, the phase of the radio-frequency signal outputted from the terminal 11c is −90°.

The signal intensity of the radio-frequency signal outputted from the terminal 11b and the radio-frequency signal outputted from the terminal 11c is one-half (decreased by 3 dB) of the radio-frequency signal RFin. The amplifier circuit 12 includes amplifiers 12-1 and 12-2. The amplifier 12-1 corresponds to a carrier amplifier. The amplifier 12-2 corresponds to a peaking amplifier.

The input terminal of the amplifier 12-1 is electrically connected to the terminal 11b of the splitter 11 via a direct-current (DC) blocking capacitor C1. The output terminal of the amplifier 12-1 is electrically connected to a terminal 13a of the Marchand balun 13 via a DC blocking capacitor C3.

The input terminal of the amplifier 12-2 is electrically connected to the terminal 11c of the splitter 11 via a DC blocking capacitor C2. The output terminal of the amplifier 12-2 is electrically connected to a terminal 14a of the Marchand balun 14 via a DC blocking capacitor C4.

The Marchand balun 13 includes quarter-wavelength coupling lines 13-1 to 13-4.

One end of the quarter-wavelength coupling line 13-1 is electrically connected to the terminal 13a. The other end of the quarter-wavelength coupling line 13-1 is electrically connected to one end of the quarter-wavelength coupling line 13-2. The other end of the quarter-wavelength coupling line 13-2 is open-circuited.

The quarter-wavelength coupling line 13-3 provides line coupling with the quarter-wavelength coupling line 13-2. One end of the quarter-wavelength coupling line 13-3 is electrically connected to a terminal 13b. The other end of the quarter-wavelength coupling line 13-3 is electrically connected to a reference potential.

The quarter-wavelength coupling line 13-4 provides line coupling with the quarter-wavelength coupling line 13-1. One end of the quarter-wavelength coupling line 13-4 is electrically connected to a terminal 13c. The other end of the quarter-wavelength coupling line 13-4 is electrically connected to a reference potential.

The terminal 13b of the Marchand balun 13 is electrically connected to the input terminal of the amplifier 15-1 via a DC blocking capacitor C5. The terminal 13c of the Marchand balun 13 is electrically connected to the input terminal of the amplifier 15-2 via a DC blocking capacitor C6.

The Marchand balun 14 includes quarter-wavelength coupling lines 14-1 to 14-4.

One end of the quarter-wavelength coupling line 14-1 is electrically connected to the terminal 14a. The other end of the quarter-wavelength coupling line 14-1 is electrically connected to one end of the quarter-wavelength coupling line 14-2. The other end of the quarter-wavelength coupling line 14-2 is open-circuited.

The quarter-wavelength coupling line 14-3 provides line coupling with the quarter-wavelength coupling line 14-2. One end of the quarter-wavelength coupling line 14-3 is electrically connected to a terminal 14b. The other end of the quarter-wavelength coupling line 14-3 is electrically connected to a reference potential.

The quarter-wavelength coupling line 14-4 provides line coupling with the quarter-wavelength coupling line 14-1. One end of the quarter-wavelength coupling line 14-4 is electrically connected to a terminal 14c. The other end of the quarter-wavelength coupling line 14-4 is electrically connected to a reference potential.

The terminal 14b of the Marchand balun 14 is electrically connected to the input terminal of the amplifier 15-3 via a DC blocking capacitor C7. The terminal 14c of the Marchand balun 14 is electrically connected to the input terminal of the amplifier 15-4 via a DC blocking capacitor C8.

The relative phase difference between the output signal of the amplifier 15-1 and the output signal of the amplifier 15-3 is 90°. For example, assuming that the phase of the output signal of the amplifier 15-1 is 0°, the phase of the output signal of the amplifier 15-2 is 180°, the phase of the output signal of the amplifier 15-3 is 90°, and the phase of the output signal of the amplifier 15-4 is 270°.

The output terminal of the amplifier 15-1 is electrically connected to a terminal 16a of the Marchand balun 16 via a DC blocking capacitor C9. The output terminal of the amplifier 15-2 is electrically connected to the terminal 16b of the Marchand balun 16 via a DC blocking capacitor C10.

The output terminal of the amplifier 15-3 is electrically connected to a terminal 17a of the Marchand balun 17 via a DC blocking capacitor C11. The output terminal of the amplifier 15-4 is electrically connected to a terminal 17b of the Marchand balun 17 via a DC blocking capacitor C12.

A terminal 16c of the Marchand balun 16 is electrically connected to the terminal 1b. The terminal 16d of the Marchand balun 16 is electrically connected to a terminal 18a of the filter 18.

A terminal 17c of the Marchand balun 17 is electrically connected to a terminal 18b of the filter 18. The filter 18 includes a first portion 18-1 and a second portion 18-2. The first portion 18-1 is electrically connected to the terminal 18a. The second portion 18-2 is electrically connected to the terminal 18b.

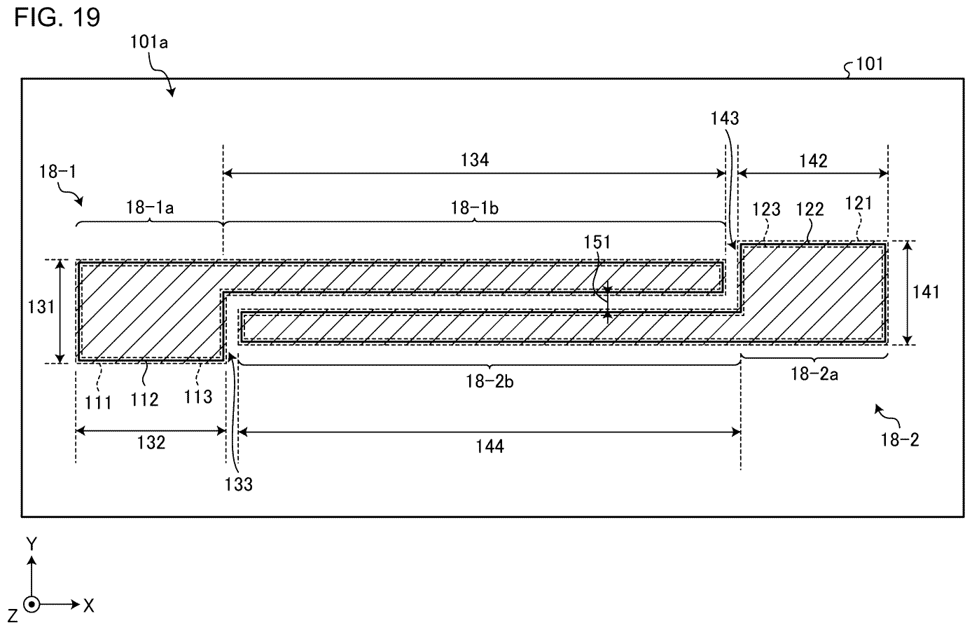

FIG. 19 illustrates the structure of the filter in the power amplifier circuit according to the first embodiment.

The filter 18 is formed on a substrate 101.

Specifically, each of the first portion 18-1 and the second portion 18-2 is formed on the substrate 101. The substrate 101 is, for example, a semiconductor substrate or a printed wiring board (PWB). However, these examples should not be interpreted as limiting the present disclosure.

At least one of the splitter 11, the amplifier circuit 12, the Marchand balun 13, the Marchand balun 14, the amplifier circuit 15, the Marchand balun 16, and the Marchand balun 17 may be formed or disposed on the substrate 101.

The substrate 101 has a major surface 101a (the major surface located on the front side in the Z-axis) that extends along the X-Y plane. FIG. 19 illustrates the substrate 101 in plan view.

As used in the present disclosure, plan view refers to viewing the major surface 101a perpendicularly to the major surface 101a. In other words, plan view refers to viewing the major surface 101a in a direction from the front side to the back side along the Z-axis.

The first portion 18-1 includes a first metal 111 as a first wiring layer (the wiring layer on the back side along the Z-axis), a second metal 112 as a second wiring layer (the wiring layer on the front side along the Z-axis), and a via 113. The first metal 111 and the second metal 112 are electrically connected via the via 113.

The second portion 18-2 includes a first metal 121 as a first wiring layer, a second metal 122 as a second wiring layer, and a via 123. The first metal 121 and the second metal 122 are electrically connected via the via 123.

In the first embodiment, each of the first portion 18-1 and the second portion 18-2 is formed of two layers of metal. However, this should not be interpreted as limiting the present disclosure. Each of the first portion 18-1 and the second portion 18-2 may be formed of one layer or three or more layers of metal.

In the first embodiment, circuit simulations are conducted assuming that the first portion 18-1 and the second portion 18-2 are formed of two layers of metal. The circuit simulation results may differ when the first portion 18-1 and the second portion 18-2 are formed by one layer or three or more layers of metal.

The longitudinal direction of each of the first portion 18-1 and the second portion 18-2 is the X direction.

The first portion 18-1 includes a third portion 18-1a and a fourth portion 18-1b.

The length 131 of the third portion 18-1a in the Y-axis direction is the length that results in a characteristic impedance of 50Ω. The specific length differs depending on factors such as the material and the dielectric permittivity of the third portion 18-1a.

The length 132 of the third portion 18-1a in the X-axis direction can be any length, since the characteristic impedance is set at 50Ω.

The fourth portion 18-1b extends from an edge 133 of the third portion 18-1a, which is located on the front side along the X-axis, toward the front side along the X-axis. In the embodiment, the fourth portion 18-1b extends from the end portion of the edge 133 on the front side along the Y-axis. However, this should not be interpreted as limiting the present disclosure. The fourth portion 18-1b may extend from the end portion of the edge 133 on the back side along the Y-axis.

The length 134 of the fourth portion 18-1b in the X-axis direction is one-fourth of the wavelength of the radio-frequency signal (for example, a radio-frequency signal at the center frequency).

The second portion 18-2 includes a fifth portion 18-2a and a sixth portion 18-2b.

The length 141 of the fifth portion 18-2a in the Y-axis direction is the length that results in a characteristic impedance of 50Ω. The specific length differs depending on factors such as the material and the dielectric permittivity of the fifth portion 18-2a.

The length 142 of the fifth portion 18-2a in the X-axis direction can be any length, since the characteristic impedance is set at 50Ω.

The sixth portion 18-2b extends from an edge 143 of the fifth portion 18-2a, which is located on the back side along the X-axis, toward the back side along the X-axis. In the embodiment, the sixth portion 18-2b extends from the end portion of the edge 143 on the back side along the Y-axis. However, this should not be interpreted as limiting the present disclosure. The sixth portion 18-2b may extend from the end portion of the edge 143 on the front side along the Y-axis.

The length 144 of the sixth portion 18-2b in the X-axis direction is one-fourth of the wavelength of the radio-frequency signal (for example, a radio-frequency signal at the center frequency).

The space 151 between the fourth portion 18-1b and the sixth portion 18-2b in the Y-axis direction is, for example, less than or equal to 5 μm (micrometers). However, this should not be interpreted as limiting the present disclosure.

The fourth portion 18-1b and the sixth portion 18-2b provide wiring coupling.

The front-end portion of the fourth portion 18-1b faces the edge 143 of the fifth portion 18-2a. The front-end portion of the sixth portion 18-2b faces the edge 133 of the third portion 18-1a.

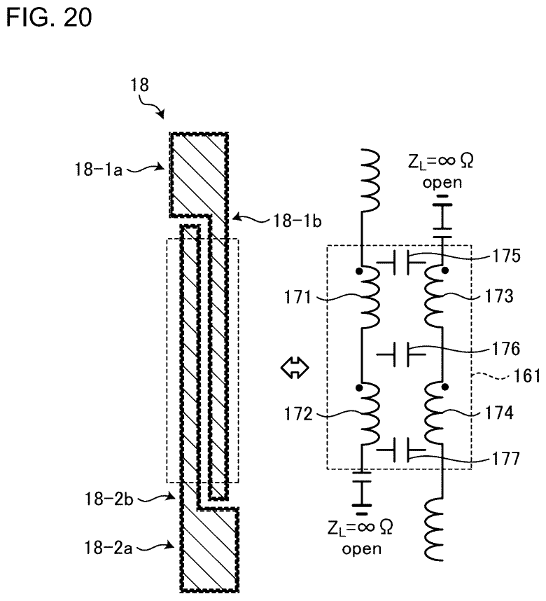

FIG. 20 illustrates the equivalent circuit of the filter in the power amplifier circuit according to the first embodiment.

The equivalent circuit 161 is equivalent to the fourth portion 18-1b and the sixth portion 18-2b of the filter 18.

The equivalent circuit 161 includes inductors 171, 172, 173, and 174.

The inductors 171 and 172 are connected in series. The inductors 173 and 174 are connected in series.

The inductors 171 and 173 are coupled. The inductors 172 and 174 are coupled.

A parasitic capacitance 175 is formed between one end of the inductor 171 and one end of the inductor 173. A parasitic capacitance 176 is formed between the other end of the inductor 171 and one end of the inductor 172, and between the other end of the inductor 173 and one end of the inductor 174. A parasitic capacitance 177 is formed between the other end of the inductor 172 and the other end of the inductor 174.

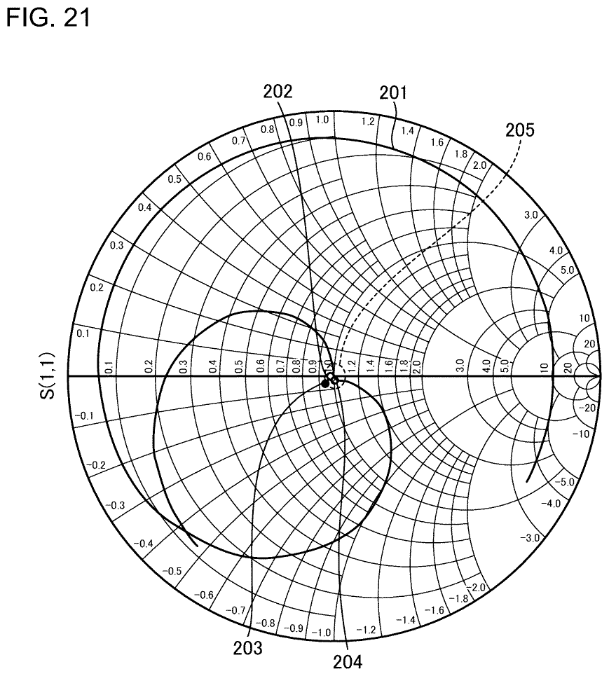

FIGS. 21 to 24 illustrate the circuit simulation results for the filter in the differential amplifier circuit according to the first embodiment.

FIG. 21 illustrates the circuit simulation results for the S-parameter S(1, 1) of the filter 18.

The line 201 illustrates S(1, 1) when the frequency of the radio-frequency signal is varied from 40 GHz to 300 GHZ. The point 202 indicates S(1, 1) at a frequency of 120 GHz. The point 203 indicates S(1, 1) at a frequency of 130 GHz. The point 204 indicates S(1, 1) at a frequency of 140 GHZ.

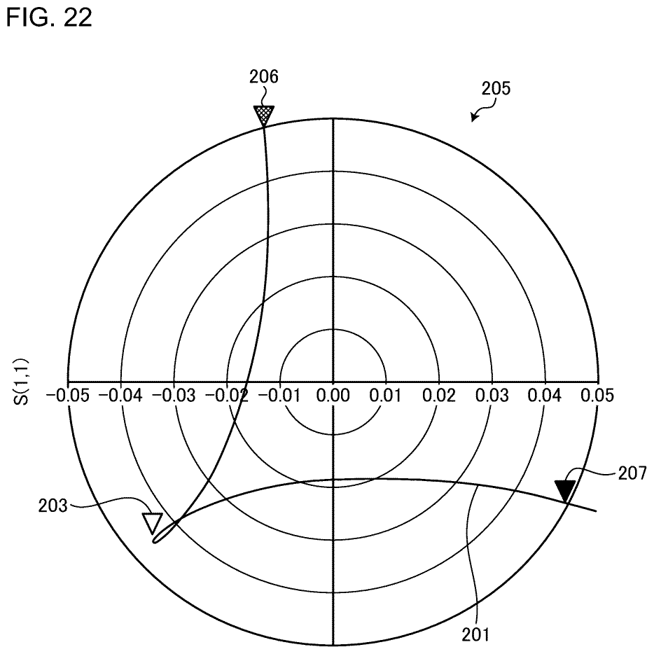

FIG. 22 is an enlarged view of the region 205 in FIG. 21. In the region 205, the output impedance of the transistors in the amplifiers 15-1 to 15-4 is at the center, and the radius is 0.05 (the absolute value of the reflection coefficient Γ is less than or equal to 0.05, that is, |Γ|≤0.05).

The point 206 indicates the minimum frequency at which the S-parameter S(1, 1) is less than or equal to 0.05. The frequency at the point 206 is 113.5 GHZ. The point 207 indicates the maximum frequency at which the S-parameter S(1,1) is less than or equal to 0.05. The frequency at the point 207 is 145.2 GHZ.

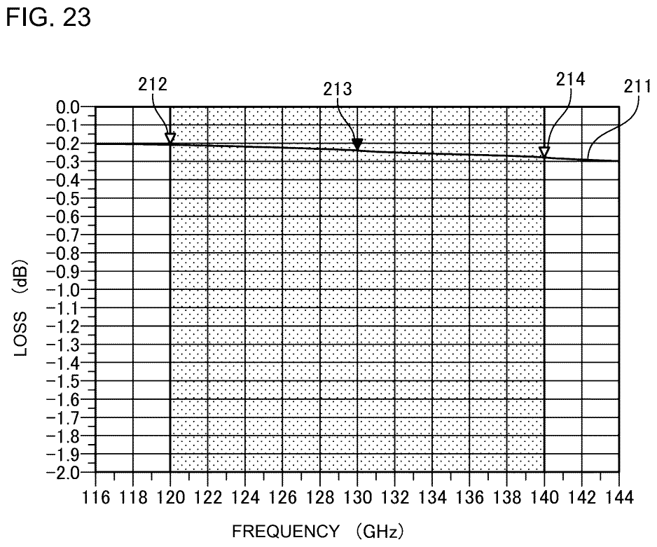

FIG. 23 illustrates the circuit simulation results for loss in the filter 18.

The line 211 illustrates the loss (dB) when the frequency of the radio-frequency signal is varied from 116 GHz to 144 GHZ. The point 212 indicates the loss (dB) at a frequency of 120 GHz. The loss at the point 212 is −0.216 dB. The point 213 indicates the loss (dB) at a frequency of 130 GHz. The loss at the point 213 is −0.238 dB. The point 214 indicates the loss (dB) at a frequency of 140 GHZ. The loss at the point 214 is −0.276 dB.

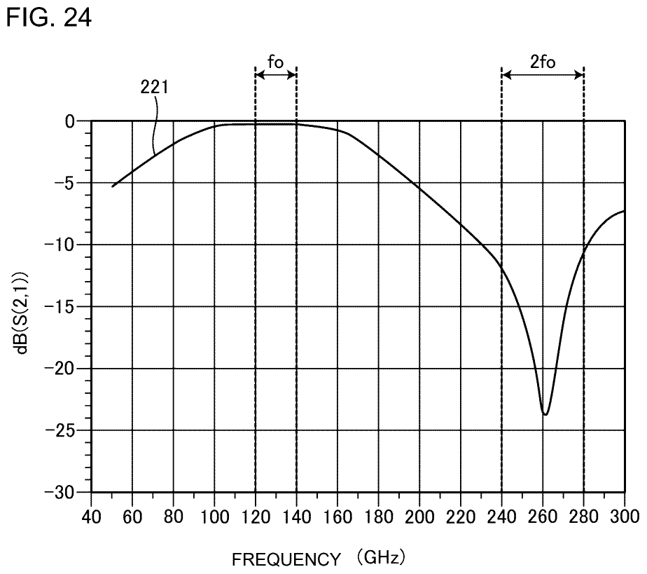

FIG. 24 illustrates the circuit simulation results for the S-parameter S(2,1) (forward transmission characteristics) of the filter 18.

The line 221 illustrates S(2,1) when the frequency of the radio-frequency signal is varied from 40 GHz to 300 GHz. The frequency band fo ranges from 120 GHz to 140 GHz. The frequency band 2fo ranges from 240 GHz to 280 GHz.

The frequency band fo has no resonance point and S(2,1) is nearly constant.

As illustrated in FIGS. 21 to 24, the filter 18 has preferable characteristics.

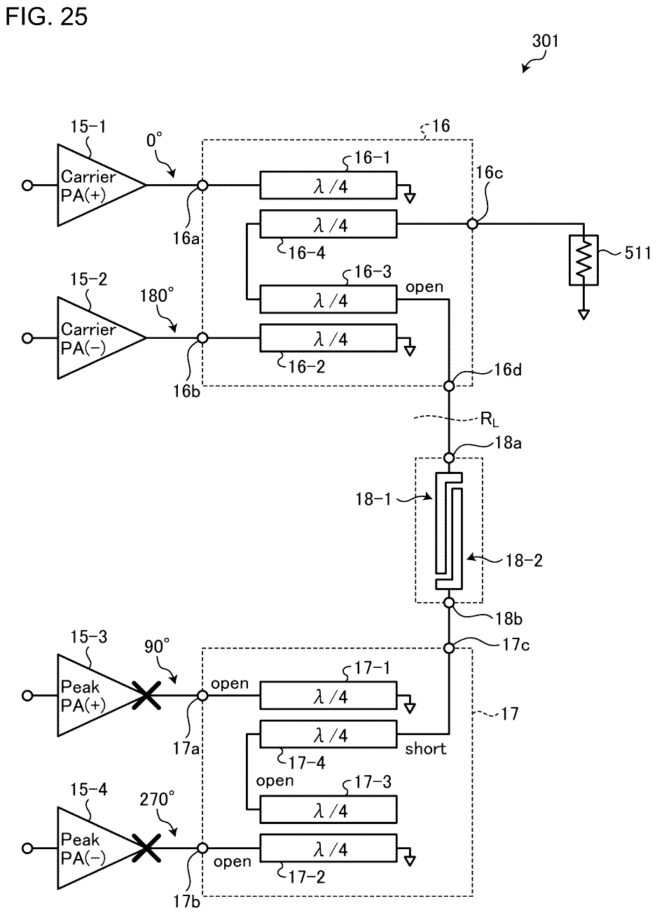

FIG. 25 illustrates the configuration of the differential amplifier circuit in the final stage of the power amplifier circuit according to the first embodiment. A differential amplifier circuit 301 in the final stage includes the final-stage (power-stage) amplifier circuit 15, the Marchand baluns 16 and 17, and the filter 18.

The same impedance as the impedance R_{L} of the load 511 appears between the terminal 16d of the Marchand balun 16 and the terminal 18a of the filter 18.

Because the filter 18 is provided, one end of the quarter-wavelength coupling line 16-3 is open-circuited when the peaking amplifiers (the amplifiers 15-3 and 15-4) do not operate.

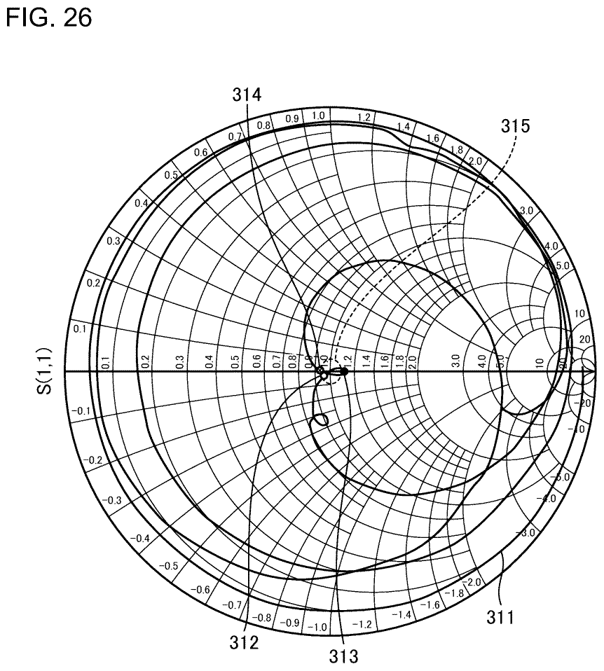

FIGS. 26 to 29 illustrate the circuit simulation results for the differential amplifier circuit in the final stage of the power amplifier circuit according to the first embodiment.

FIG. 26 illustrates the circuit simulation results for the S-parameter S(1, 1) of the Marchand balun 16 when the carrier amplifiers (the amplifiers 15-1 and 15-2) operate while the peaking amplifiers (the amplifiers 15-3 and 15-4) do not operate.

The line 311 illustrates S(1, 1) when the frequency of the radio-frequency signal is varied from 40 GHz to 300 GHZ. The point 312 indicates S(1, 1) at a frequency of 120 GHz. The point 313 indicates S(1, 1) at a frequency of 130 GHz. The point 314 indicates S(1, 1) at a frequency of 140 GHz.

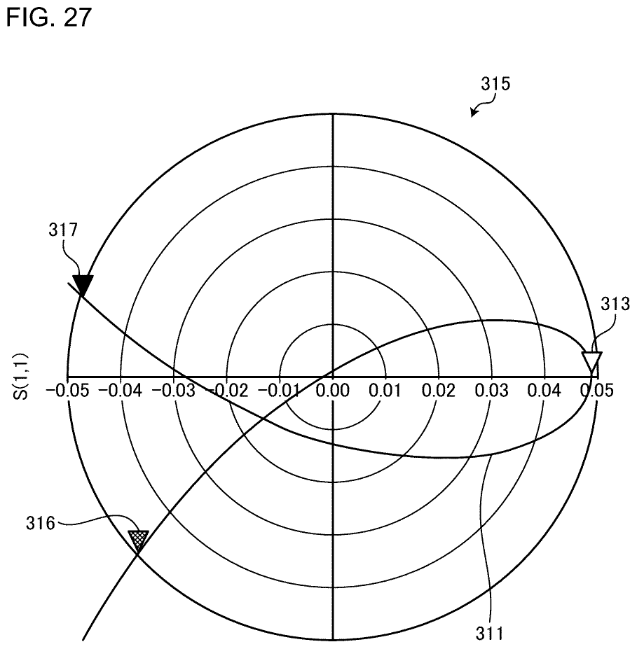

FIG. 27 is an enlarged view of the region 315 in FIG. 26. In the region 315, the output impedance of the transistors in the amplifiers 15-1 to 15-4 is at the center, and the radius is 0.05 (the absolute value of the reflection coefficient Γ is less than or equal to 0.05, that is, |Γ|≤ 0.05).

The point 316 indicates the minimum frequency at which the S-parameter S(1, 1) is less than or equal to 0.05. The frequency at the point 526 is 118.7 GHZ. The point 317 indicates the maximum frequency at which the S-parameter S(1, 1) is less than or equal to 0.05. The frequency at the point 317 is 140.9 GHZ.

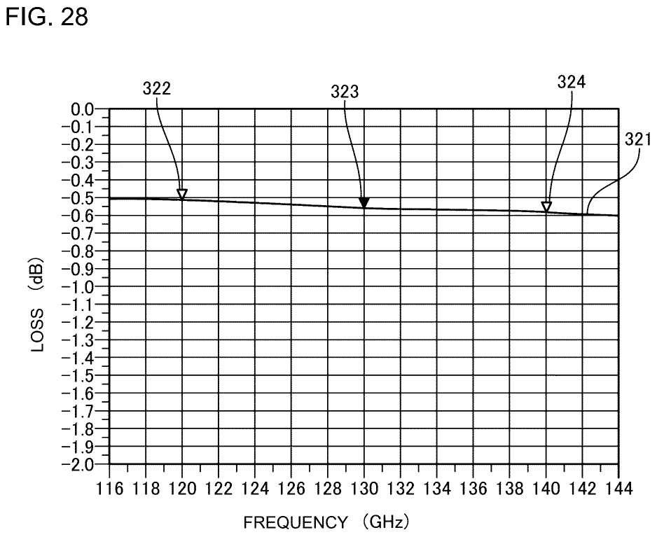

FIG. 28 illustrates the circuit simulation results for loss in the differential amplifier circuit 301 when the carrier amplifiers (the amplifiers 15-1 and 15-2) operate while the peaking amplifiers (the amplifiers 15-3 and 15-4) do not operate.

The line 321 illustrates the loss (dB) when the frequency of the radio-frequency signal is varied from 116 GHz to 144 GHz. The point 322 indicates the loss (dB) at a frequency of 120 GHz. The loss at the point 322 is −0.511 dB. The point 323 indicates the loss (dB) at a frequency of 130 GHz. The loss at the point 323 is −0.558 dB. The point 324 indicates the loss (dB) at a frequency of 140 GHz. The loss at the point 324 is −0.579 dB.

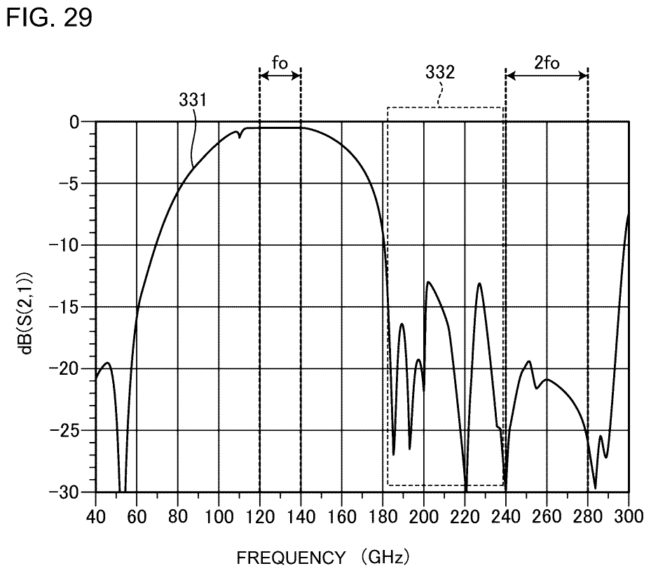

FIG. 29 illustrates the circuit simulation results for the S-parameter S(2,1) (forward transmission characteristics) of the differential amplifier circuit 301 when the carrier amplifiers (the amplifiers 15-1 and 15-2) operate while the peaking amplifiers (the amplifiers 15-3 and 15-4) do not operate.

The line 331 illustrates S(2,1) when the frequency of the radio-frequency signal is varied from 40 GHz to 300 GHz. The frequency band fo ranges from 120 GHz to 140 GHz. The frequency band 2fo ranges from 240 GHz to 280 GHz.

### Effects

### (1) Forward Transmission Characteristics

The forward transmission characteristics in the case where the carrier amplifiers operate while the peaking amplifiers do not operate in the first embodiment (see FIG. 29) will be compared with the forward transmission characteristics in the first comparative example (see FIG. 5) and the forward transmission characteristics in the case where the carrier amplifiers operate while the peaking amplifiers do not operate in the third comparative example (see FIG. 15).

In the first comparative example, the frequency band fo has no resonance point and the forward transmission characteristics are nearly constant, as illustrated in FIG. 5.

When the carrier amplifiers operate while the peaking amplifiers do not operate in the third comparative example, the resonance point 743 is present at 120 GHz, as illustrated in FIG. 15.

When the carrier amplifiers operate while the peaking amplifiers do not operate in the first embodiment, multiple resonance points are shifted, with respect to frequency, to the frequency band 332 from 180 GHz to 240 GHz, as illustrated in FIG. 29.

As described above, when the carrier amplifiers operate while the peaking amplifiers do not operate in the first embodiment, as in the first comparative example (the stand-alone differential amplifier circuit), the frequency band fo has no resonance point, and preferable forward transmission characteristics can be achieved.

### (2) Loss Characteristics

The loss characteristics in the case where the carrier amplifiers operate while the peaking amplifiers do not operate in the first embodiment (see FIG. 28) will be compared with the loss characteristics in the first comparative example (see FIG. 4) and the loss characteristics in the case where the carrier amplifiers operate while the peaking amplifiers do not operate in the third comparative example (see FIG. 14).

In the first comparative example, the loss is nearly constant in the frequency band from 120 GHz to 140 GHz, as illustrated in FIG. 4.

When the carrier amplifiers operate while the peaking amplifiers do not operate in the third comparative example, the loss at 120 GHz is significantly large, as illustrated in FIG. 14.

When the carrier amplifiers operate while the peaking amplifiers do not operate in the first embodiment, the loss is nearly constant over the frequency band from 120 GHz to 140 GHz, as illustrated in FIG. 28.

As described above, when the carrier amplifiers operate while the peaking amplifiers do not operate in the first embodiment, as in the first comparative example (the stand-alone differential amplifier circuit), preferable loss characteristics can be achieved.

### (3) Frequency Band

The frequency band in the case where the carrier amplifiers operate while the peaking amplifiers do not operate in the first embodiment (see FIG. 27) will be compared with the frequency band in the first comparative example (see FIG. 3) and the frequency band in the case where the carrier amplifiers operate while the peaking amplifiers do not operate in the third comparative example (see FIG. 13).

In the first comparative example, |Γ|≤0.05 in the frequency band from 119.7 GHZ to 140.1 GHZ, as illustrated in FIG. 3.

When the carrier amplifiers operate while the peaking amplifiers do not operate in the third comparative example, |Γ|≤0.05 is not satisfied at any frequency, as illustrated in FIG. 13.

When the carrier amplifiers operate while the peaking amplifiers do not operate in the first embodiment, |Γ|≤0.05 is satisfied over the frequency band from 118.7 GHz to 140.9 GHZ, as illustrated in FIG. 27.

As described above, when the carrier amplifiers operate while the peaking amplifiers do not operate in the first embodiment, as in the first comparative example (the stand-alone differential amplifier circuit), a wide frequency band can be achieved.

### Second Embodiment

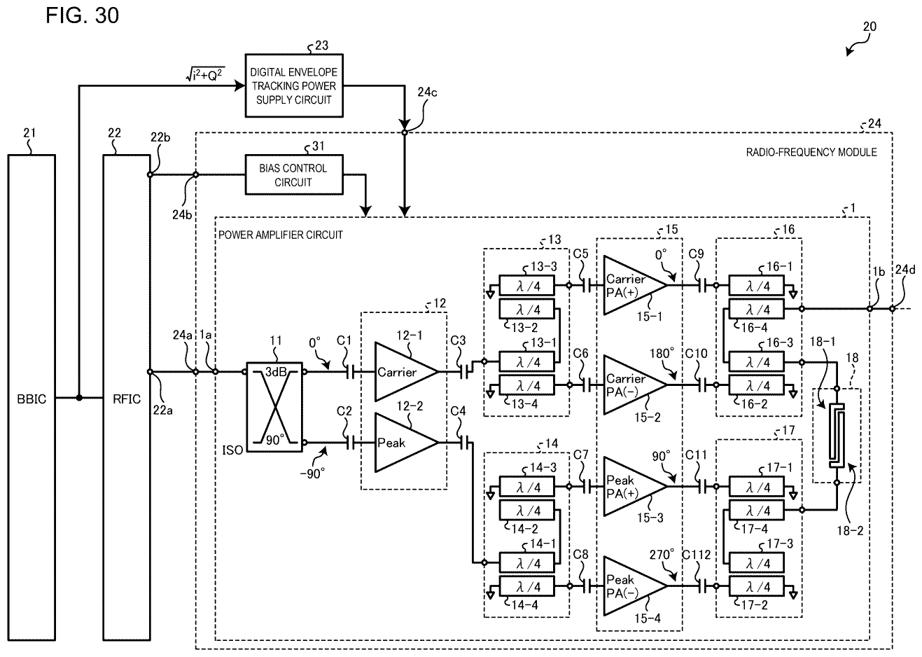

FIG. 30 illustrates the configuration of a communication circuit according to a second embodiment.

A communication circuit 20 includes a baseband signal processing circuit (BBIC) 21, a radio-frequency signal processing circuit (RFIC) 22, a digital envelope tracking power supply circuit 23, and a radio-frequency module 24. The radio-frequency module 24 includes the power amplifier circuit 1 and a bias control circuit 31.

The baseband signal processing circuit 21 outputs a baseband signal to the radio-frequency signal processing circuit 22. The radio-frequency signal processing circuit 22 converts the baseband signal into a radio-frequency signal and outputs the radio-frequency signal to the splitter 11 through terminals 22a and 24a and the terminal 1a. The radio-frequency signal processing circuit 22 outputs a signal representing the signal level (signal intensity) of the radio-frequency signal to the bias control circuit 31 through terminals 22b and 24b.

The digital envelope tracking power supply circuit 23 supplies a power supply voltage based on √(i²+Q²) of the baseband signal through a terminal 24c to the amplifiers 12-1 and 12-2 and to the amplifiers 15-1 to 15-4.

When the signal level of the radio-frequency signal is less than a threshold, the bias control circuit 31 supplies a bias to the carrier amplifiers (the amplifiers 12-1, 15-1, and 15-2). When the signal level of the radio-frequency signal is greater than or equal to the threshold, the bias control circuit 31 supplies a bias to both the carrier amplifiers (the amplifiers 12-1, 15-1, and 15-2) and the peaking amplifiers (the amplifiers 12-2, 15-3, and 15-4).

A terminal 24d of the radio-frequency module 24 is, for example, electrically connected to an element such as an antenna or a front-end circuit. However, this should not be interpreted as limiting the present disclosure.

The above embodiments have been described for ease of understanding the present disclosure and should not be interpreted as limiting the present disclosure. The present disclosure may be changed or improved without departing from its spirit, and the present disclosure also includes equivalents thereof.

What is claimed is:

1. A power amplifier circuit comprising:
a first amplifier, a second amplifier, a third amplifier, and a fourth amplifier;
a first Marchand balun having a first terminal electrically connected to an output terminal of the first amplifier, a second terminal electrically connected to an output terminal of the second amplifier, and a third terminal electrically connected to an output terminal;
a second Marchand balun having a first terminal electrically connected to an output terminal of the third amplifier, and a second terminal electrically connected to an output terminal of the fourth amplifier; and
a filter electrically connected between a fourth terminal of the first Marchand balun and a third terminal of the second Marchand balun,
wherein the filter has a first portion and a second portion that are on a substrate,
wherein the first portion has:
a third portion having a length in a first direction when viewed perpendicularly to the substrate, the length resulting in a predetermined characteristic impedance, and
a fourth portion extending in a second direction that intersects the first direction when viewed perpendicularly to the substrate, the fourth portion extending from a first edge of the third portion, the first edge being located on a side in the second direction, the fourth portion having a length in the second direction that is one-fourth of a wavelength of a radio-frequency signal,
wherein the second portion has:
a fifth portion having a length in the first direction when viewed perpendicularly to the substrate, the length resulting in the characteristic impedance, and
a sixth portion extending in a third direction opposite to the second direction when viewed perpendicularly to the substrate, the sixth portion extending from a second edge of the fifth portion, the second edge being located on a side in the third direction, the sixth portion having a length in the third direction that is one-fourth of a wavelength of a radio-frequency signal, and
wherein the fourth portion and the sixth portion are spaced apart from and parallel to each other when viewed perpendicularly to the substrate, and are configured to provide line coupling.

2. The power amplifier circuit according to claim 1,
wherein a front-end portion of the fourth portion is located on a side in the second direction when viewed perpendicularly to the substrate, and is spaced apart from and faces the second edge of the fifth portion, and
wherein a front-end portion of the sixth portion is located on a side in the third direction when viewed perpendicularly to the substrate, is spaced apart from and faces the first edge of the third portion.

3. The power amplifier circuit according to claim 1,
wherein the first amplifier and the second amplifier constitute a first differential amplifier circuit, and
wherein the third amplifier and the fourth amplifier constitute a second differential amplifier circuit.

4. The power amplifier circuit according to claim 2,
wherein the first amplifier and the second amplifier constitute a first differential amplifier circuit, and
wherein the third amplifier and the fourth amplifier constitute a second differential amplifier circuit.

5. The power amplifier circuit according to claim 1,
wherein the first amplifier and the second amplifier are carrier amplifiers, and
wherein the third amplifier and the fourth amplifier are peaking amplifiers.

6. The power amplifier circuit according to claim 2,
wherein the first amplifier and the second amplifier are carrier amplifiers, and
wherein the third amplifier and the fourth amplifier are peaking amplifiers.

7. The power amplifier circuit according to claim 3,
wherein the first amplifier and the second amplifier are carrier amplifiers, and
wherein the third amplifier and the fourth amplifier are peaking amplifiers.

8. The power amplifier circuit according to claim 1, further comprising:
a fifth amplifier and a sixth amplifier;
a third Marchand balun having a first terminal electrically connected to an output terminal of the fifth amplifier, a second terminal electrically connected to an input terminal of the first amplifier, and a third terminal electrically connected to an input terminal of the second amplifier; and
a fourth Marchand balun having a first terminal electrically connected to an output terminal of the sixth amplifier, a second terminal electrically connected to an input terminal of the third amplifier, and a third terminal electrically connected to an input terminal of the fourth amplifier.

9. The power amplifier circuit according to claim 2, further comprising:
a fifth amplifier and a sixth amplifier;
a third Marchand balun having a first terminal electrically connected to an output terminal of the fifth amplifier, a second terminal electrically connected to an input terminal of the first amplifier, and a third terminal electrically connected to an input terminal of the second amplifier; and
a fourth Marchand balun having a first terminal electrically connected to an output terminal of the sixth amplifier, a second terminal electrically connected to an input terminal of the third amplifier, and a third terminal electrically connected to an input terminal of the fourth amplifier.

10. The power amplifier circuit according to claim 3, further comprising:
a fifth amplifier and a sixth amplifier;
a third Marchand balun having a first terminal electrically connected to an output terminal of the fifth amplifier, a second terminal electrically connected to an input terminal of the first amplifier, and a third terminal electrically connected to an input terminal of the second amplifier; and
a fourth Marchand balun having a first terminal electrically connected to an output terminal of the sixth amplifier, a second terminal electrically connected to an input terminal of the third amplifier, and a third terminal electrically connected to an input terminal of the fourth amplifier.

11. The power amplifier circuit according to claim 5, further comprising:
a fifth amplifier and a sixth amplifier;
a third Marchand balun having a first terminal electrically connected to an output terminal of the fifth amplifier, a second terminal electrically connected to an input terminal of the first amplifier, and a third terminal electrically connected to an input terminal of the second amplifier; and
a fourth Marchand balun having a first terminal electrically connected to an output terminal of the sixth amplifier, a second terminal electrically connected to an input terminal of the third amplifier, and a third terminal electrically connected to an input terminal of the fourth amplifier.

12. The power amplifier circuit according to claim 8, further comprising:
a splitter having a first terminal electrically connected to an input terminal configured to receive a single-ended radio-frequency signal, a second terminal electrically connected to an input terminal of the fifth amplifier, and a third terminal electrically connected to an input terminal of the sixth amplifier.

13. A communication circuit comprising:
a radio-frequency signal processing circuit configured to process a radio-frequency signal; and
the power amplifier circuit according to claim 1, the power amplifier circuit being in a signal path between the radio-frequency signal processing circuit and an antenna.
